(19) United States
(12) Patent Application Publication
(10) Pub. No.: US 2025/0143111 A1
(43) Pub. Date: May 1, 2025

(54) Display Substrate and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Zhengkun LI, Beijing (CN); Meng LI, Beijing (CN); Benlian WANG, Beijing (CN); Xiaohuan CHANG, Beijing (CN)

(21) Appl. No.: 18/692,341

(22) PCT Filed: Aug. 10, 2023
(86) PCT No.: PCT/CN2023/112180

§ 371 Date: Mar. 15, 2024

(30) Foreign Application Priority Data
Sep. 13, 2022 (CN) 202211111570.9

(51) Int. Cl. H10K 59/131; H10H 29/34; H10H 29/49; H10K 59/35

(52) U.S. Cl. CPC H10K 59/131; H10H 29/34; H10H 29/49; H10K 59/353

(57) ABSTRACT

A display substrate includes a base substrate, multiple light emitting elements, and multiple pixel circuits. The multiple light emitting elements include multiple groups of light emitting elements. At least one of the multiple groups of light emitting elements includes multiple first region light emitting elements located in a first display region and multiple second region light emitting elements located in a second display region. The multiple pixel circuits include multiple groups of pixel circuits. At least one of the multiple groups of pixel circuits includes multiple first type pixel circuits and multiple second type pixel circuits. The multiple first region light emitting elements at least include multiple first light emitting elements emitting light in a first color and multiple second light emitting elements emitting light in a second color. The multiple first type pixel circuits include multiple first pixel circuits and multiple second pixel circuits.

### CROSS-REFERENCE TO RELATED APPLICATION

The present application is a U.S. National Phase Entry of International Application No. PCT/CN2023/112180 having an international filing date of Aug. 10, 2023, which claims the priority to the Chinese Patent Application No. 202211111570.9, entitled “DISPLAY SUBSTRATE AND DISPLAY APPARATUS”, filed on Sep. 13, 2022, to the CNIPA. The above-identified applications are incorporated herein by reference in their entireties.

### TECHNICAL FIELD

The present disclosure relates to, but is not limited to, the field of display technologies, in particular to a display substrate and a display apparatus.

### BACKGROUND

Organic Light Emitting Diodes (OLED's) and Quantum-dot Light Emitting Diodes (QLED's) are active light emitting display devices and have advantages of self-illumination, a wide viewing angle, a high contrast ratio, low power consumption, an extremely high reaction speed, lightness and thinness, flexibility, and low cost, etc. A full display with camera technology is a novel technology proposed for increasing a screen-to-body ratio of a display apparatus.

### SUMMARY

The following is a summary of subject matter described herein in detail. The summary is not intended to limit the protection scope of the claims.

Embodiments of the present disclosure provide a display substrate and a display apparatus.

In one aspect, a display substrate is provided in an embodiment of the present disclosure, which includes a base substrate, a plurality of light emitting elements, and a plurality of pixel circuits. The base substrate includes a first display region and a second display region located on at least one side of the first display region. The plurality of light emitting elements are located in the first display region and the second display region, wherein the plurality of light emitting elements include a plurality of groups of light emitting elements, each group of light emitting elements is arranged along a first direction, the plurality of groups of light emitting elements are arranged along a second direction, at least one group of light emitting elements in the plurality of groups of light emitting elements includes a plurality of first region light emitting elements and a plurality of second region light emitting elements, the plurality of first region light emitting elements are located in the first display region, and the plurality of second region light emitting elements are located in the second display region. The plurality of pixel circuits are located in the second display region, wherein the plurality of pixel circuits include a plurality of groups of pixel circuits, each group of pixel circuits is arranged along the first direction, the plurality of groups of pixel circuits are arranged along the second direction, at least one group of pixel circuits in the plurality of groups of pixel circuits includes a plurality of first type pixel circuits and a plurality of second type pixel circuits, the plurality of first type pixel circuits are arranged at intervals between the plurality of second type pixel circuits. At least one first type pixel circuit in the plurality of first type pixel circuits is electrically connected to at least one first region light emitting element in the plurality of first region light emitting elements, and at least one second type pixel circuit in the plurality of second type pixel circuits is electrically connected to at least one second region light emitting element in the plurality of second region light emitting elements. The plurality of first region light emitting elements at least include a plurality of first light emitting elements emitting light in a first color and a plurality of second light emitting elements emitting light in a second color; the plurality of first type pixel circuits at least include a plurality of first pixel circuits and a plurality of second pixel circuits; the plurality of first light emitting elements are electrically connected to the plurality of first pixel circuits through a plurality of first conductive lines, and the plurality of second light emitting elements are electrically connected to the plurality of second pixel circuits through a plurality of second conductive lines. A plurality of first pixel circuits electrically connected to a plurality of first light emitting elements in the at least one group of light emitting elements and a plurality of second pixel circuits electrically connected to a plurality of second light emitting elements in the at least one group of light emitting elements are located in different groups of pixel circuits; the first direction intersects with the second direction.

In some exemplary implementations, the plurality of first pixel circuits electrically connected to the plurality of first light emitting elements in the at least one group of light emitting elements are located in a pixel circuit group adjacent to a pixel circuit group where the plurality of second pixel circuits electrically connected to the plurality of second light emitting elements in the at least one group of light emitting elements are located, in the second direction.

In some exemplary implementations, the plurality of first region light emitting elements further include a plurality of third light emitting elements emitting light in a third color; the plurality of first type pixel circuits further include a plurality of third pixel circuits, wherein the plurality of third light emitting elements are electrically connected to the plurality of third pixel circuits through a plurality of third conductive lines. A plurality of third pixel circuits electrically connected to a plurality of third light emitting elements in the at least one group of light emitting elements and a plurality of first pixel circuits electrically connected to a plurality of first light emitting elements in the at least one group of light emitting elements are located in a same group of pixel circuits; or, a plurality of third pixel circuits electrically connected to a plurality of third light emitting elements in the at least one group of light emitting elements and a plurality of second pixel circuits electrically connected to a plurality of second light emitting elements in the at least one group of light emitting elements are located in a same group of pixel circuits.

In some exemplary implementations, the first conductive lines, the second conductive lines, and the third conductive lines are of a same layer structure.

In some exemplary implementations, a plurality of third pixel circuits electrically connected to a plurality of third light emitting elements in the at least one group of light emitting elements are closer to the first display region than a plurality of first pixel circuits electrically connected to a plurality of first light emitting elements and a plurality of second pixel circuits electrically connected to a plurality of second light emitting elements in the at least one group of light emitting elements.

In some exemplary implementations, the at least one third pixel circuit is electrically connected to n1 third light emitting elements and configured to drive the n1 third light emitting elements to emit light, and the at least one third pixel circuit is electrically connected to n2 third light emitting elements and configured to drive the n2 third light emitting elements to emit light, where both n1 and n2 are integers greater than or equal to 2 and n1 is different from n2.

In some exemplary implementations, the n1 third light emitting elements serve as first light emitting units, and the n2 third light emitting elements serve as second light emitting units, the first light emitting units and the second light emitting units are arranged at intervals along the first direction or periodically in an order of a first light emitting unit, a second light emitting unit, a second light emitting unit and a first light emitting unit.

In some exemplary implementations, the display substrate further includes a plurality of third connection lines located in the first display region, and the n1 third light emitting elements or the n2 third light emitting elements are electrically connected by one third connection line.

In some exemplary implementations, the plurality of third conductive lines electrically connected to the plurality of third pixel circuits and the plurality of first conductive lines electrically connected to the plurality of first pixel circuits, which are located in a same group of pixel circuits, are located on opposite sides of the group of pixel circuits in the second direction; or, the plurality of third conductive lines electrically connected to the plurality of third pixel circuits and the plurality of second conductive lines electrically connected to the plurality of second pixel circuits, which are located in a same group of pixel circuits, are located on opposite sides of the group of pixel circuits in the second direction.

In some exemplary implementations, the light in the first color is red light, the light in the second color is blue light, and the light in the third color is green light.

In some exemplary implementations, at least one first pixel circuit of the plurality of first pixel circuits is electrically connected to m1 first light emitting elements and is configured to drive the m1 first light emitting elements to emit light; at least one second pixel circuit of the plurality of second pixel circuits is electrically connected to m2 second light emitting elements and is configured to drive the m2 second light emitting elements to emit light, wherein both m1 and n2 are integers greater than or equal to 2.

In another aspect, a display substrate is provided in an embodiment of the present disclosure, which includes the aforementioned display substrate.

Other aspects of the present disclosure may be comprehended after the drawings and the detailed descriptions are read and understood.

### BRIEF DESCRIPTION OF DRAWINGS

Accompanying drawings are used for providing further understanding of technical solutions of the present disclosure, constitute a part of the specification, and are used for explaining the technical solutions of the present disclosure together with embodiments of the present disclosure, but do not constitute limitations on the technical solutions of the present disclosure. Shapes and sizes of one or more components in the drawings do not reflect actual scales, but are only intended to schematically describe contents of the present disclosure.

FIG. 1 is a schematic diagram of a display substrate according to at least one embodiment of the present disclosure.

FIG. 2 is a partially schematic diagram of a display substrate according to at least one embodiment of the present disclosure.

FIG. 3 illustrates schematically a plan view of a part of a display substrate according to at least one embodiment of the present disclosure.

FIG. 4 illustrates schematically a wiring connection diagram of a display substrate according to at least one embodiment of the present disclosure.

FIG. 5 is a partially schematic diagram of a second display region according to at least one embodiment of the present disclosure.

FIG. 6 illustrates schematically a partially wiring diagram of a second display region according to at least one embodiment of the present disclosure.

FIGS. 7A to 7C are partially schematic diagrams in FIG. 5.

FIG. 8 is a partially schematic diagram of a first display region according to at least one embodiment of the present disclosure.

FIG. 9 illustrates schematically a partially wiring diagram of a first display region according to at least one embodiment of the present disclosure.

FIG. 10 illustrates schematically a partially wiring diagram of a first display region according to at least one embodiment of the present disclosure.

FIG. 11 illustrates schematically a sectional view of a part of a display substrate according to at least one embodiment of the present disclosure.

FIG. 12 illustrates schematically another partial plan view of a display substrate according to at least one embodiment of the present disclosure.

FIG. 13 illustrates schematically another partial plan view of a display substrate according to at least one embodiment of the present disclosure.

FIG. 14 is a schematic diagram of a display apparatus according to at least one embodiment of the present disclosure.

### DETAILED DESCRIPTION

The embodiments of the present disclosure will be described below with reference to the drawings in detail. Implementations may be implemented in multiple different forms. Those of ordinary skills in the art may easily understand such a fact that modes and contents may be transformed into other forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one mode of the present disclosure is not necessarily limited to the size, and a shape and a size of one or more components in the drawings do not reflect an actual scale. In addition, the accompanying drawings schematically illustrate ideal examples, and a mode of the present disclosure is not limited to shapes, numerical values, or the like shown in the drawings.

Ordinal numerals “first”, “second”, “third”, etc., in the specification are set not to form limits in numbers but only to avoid confusion between composition elements. In the present disclosure, “a plurality of” represents two or more than two.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved apparatuses or elements are required to have specific orientations and be structured and operated with the specific orientations but only to easily and simply describe the present specification, and thus should not be understood as limitations on the present disclosure. The positional relationships between the constituent elements are changed as appropriate according to a direction with which the constituent elements are described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, it may be a fixed connection, a detachable connection, or an integral connection; it may be a mechanical connection or a connection; it may be a direct connection, an indirect connection through a middleware, or internal communication inside two elements. Those of ordinary skills in the art may understand meanings of the aforementioned terms in the present disclosure according to situations.

In the specification, “electrical connection” includes connection of composition elements through an element with some electrical function. The “element having some electrical function” is not particularly limited as long as electrical signals between the connected constituent elements may be transmitted. Examples of the “element having some electrical function” not only include an electrode and a wiring, but also include a switching element such as a transistor, a resistor, an inductor, a capacitor, another element with multiple functions, etc.

In the specification, a transistor refers to an element which at least includes three terminals, i.e., a gate, a drain, and a source. The transistor has a channel region between the drain (drain electrode terminal, drain region, or drain electrode) and the source (source electrode terminal, source region, or source electrode), and a current can flow through the drain, the channel region, and the source. In the specification, the channel region refers to a region through which a current mainly flows.

In the specification, a first electrode may be a drain and a second electrode may be a source, or, a first electrode may be a source and a second electrode may be a drain. In a case that transistors with opposite polarities are used, or in a case that a direction of a current is changed during operation of a circuit, or the like, functions of the “source” and the “drain” are sometimes interchangeable. Therefore, the “source” and the “drain” are interchangeable in the specification.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

A triangle, rectangle, trapezoid, pentagon, or hexagon, etc. in the specification is not strictly defined, and it may be an approximate triangle, rectangle, trapezoid, pentagon, or hexagon, etc. There may be some small deformations caused by tolerance, and there may be a chamfer, an arc edge, and deformation, etc.

A “light transmittance” in the present disclosure refers to an ability of light to pass through a medium, and is a percentage of luminous flux passing through a transparent or translucent body to its incident luminous flux.

In the present disclosure, “about” and “substantially” refer to that a boundary is not defined strictly and a case within a range of process and measurement errors is allowed. In the present disclosure, “substantially the same” refers to a case where numerical values differ by less than 10%.

A display substrate is provided in at least one embodiment of the present disclosure, which includes a base substrate, a plurality of light emitting elements and a plurality of pixel circuits. The base substrate includes a first display region and a second display region located on at least one side of the first display region. The plurality of light emitting elements are located in the first display region and the second display region. The plurality of light emitting elements include a plurality of groups of light emitting elements, each group of light emitting elements is arranged in a first direction, and the plurality of groups of light emitting elements are arranged in a second direction. At least one group of light emitting elements in the plurality of groups of light emitting elements includes a plurality of first region light emitting elements and a plurality of second region light emitting elements, the plurality of first region light emitting elements are located in the first display region, and the plurality of second region light emitting elements are located in the second display region. The plurality of pixel circuits are located in the second display region, wherein the plurality of pixel circuits include a plurality of groups of pixel circuits, each group of pixel circuits is arranged along the first direction, the plurality of groups of pixel circuits are arranged along the second direction. At least one group of pixel circuits in the plurality of groups of pixel circuits includes a plurality of first type pixel circuits and a plurality of second type pixel circuits, the plurality of first type pixel circuits are arranged at intervals between the plurality of second type pixel circuits. At least one first type pixel circuit in the plurality of first type pixel circuits is electrically connected to at least one first region light emitting element in the plurality of first region light emitting elements, and at least one second type pixel circuit in the plurality of second type pixel circuits is electrically connected to at least one second region light emitting element in the plurality of second region light emitting elements. The plurality of first region light emitting elements at least include a plurality of first light emitting elements emitting light in a first color and a plurality of second light emitting elements emitting light in a second color. The plurality of second type pixel circuits include a plurality of first pixel circuits and a plurality of second pixel circuits. A plurality of first light emitting elements are electrically connected to the plurality of first pixel circuits through a plurality of first conductive lines. A plurality of second light emitting elements are electrically connected to the plurality of second pixel circuits through a plurality of second conductive lines. A plurality of first pixel circuits electrically connected to a plurality of first light emitting elements in the at least one group of light emitting elements and a plurality of second pixel circuits electrically connected to a plurality of second light emitting elements in the at least one group of light emitting elements are located in different groups of pixel circuits. The first direction intersects with the second direction. For example, the first direction may be perpendicular to the second direction.

In some examples a group of light emitting elements may be a row of light emitting elements, and a group of pixel circuits may be a row of pixel circuits. For example, a plurality of first pixel circuits electrically connected to a plurality of first light emitting elements in one row of light emitting elements and a plurality of second pixel circuits electrically connected to a plurality of second light emitting elements in the row of light emitting elements are located in different rows of pixel circuits.

According to the display substrate provided in this example, by disposing a plurality of first pixel circuits electrically connected to a plurality of first light emitting elements in the at least one group of light emitting elements and a plurality of second pixel circuits electrically connected to a plurality of second light emitting elements in the at least one group of light emitting elements being located in different groups of pixel circuits, lengths of the first conductive lines and the second conductive lines can be shortened, thereby reducing a difference between loads in different conductive lines, reducing a difference between brightness in the first display region and in the second display region, and improving a display effect of the display substrate.

In some exemplary implementations, the plurality of first pixel circuits electrically connected to the plurality of first light emitting elements in the at least one group of light emitting elements may be located in a pixel circuit group adjacent to a pixel circuit group where the plurality of second pixel circuits electrically connected to the plurality of second light emitting elements in the at least one group of light emitting elements are located, in the second direction. For example, one row of first region light emitting elements may correspond to two rows of first type pixel circuits. In this way, a length of a conductive line connecting a first region light emitting element with a first type pixel circuit can be shortened.

In some exemplary implementations, the plurality of first region light emitting elements may further include a plurality of third light emitting elements emitting light in a third color. The plurality of first type pixel circuits may further include a plurality of third pixel circuits, wherein the plurality of third light emitting elements are electrically connected to the plurality of third pixel circuits through a plurality of third conductive lines. A plurality of third pixel circuits electrically connected to a plurality of third light emitting elements in the at least one group of light emitting elements may be located in a same group of pixel circuits as a plurality of first pixel circuits electrically connected to a plurality of first light emitting elements in the at least one group of light emitting elements; or, a plurality of third pixel circuits electrically connected to a plurality of third light emitting elements in the at least one group of light emitting elements may be located in a same group of pixel circuits as a plurality of second pixel circuits electrically connected to a plurality of second light emitting elements in the at least one group of light emitting elements. Arrangement of the pixel circuits in this example is beneficial to shortening the length of the conductive line connecting the first region light emitting element and the first type pixel circuit. However, the embodiment is not limited thereto. For example, a plurality of third pixel circuits electrically connected to a plurality of third light emitting elements of at least one group of light emitting elements may be located in different groups of pixel circuits from a plurality of first pixel circuits electrically connected to a plurality of first light emitting elements, and a plurality of second pixel circuits electrically connected to a plurality of second light emitting elements. For example, one row of first region light emitting elements may be electrically connected to three rows of first type pixel circuits, correspondingly.

In some exemplary implementations, the first conductive lines, the second conductive lines, and the third conductive lines may be of a same layer structure. For example, the first conductive lines, the second conductive lines and the third conductive lines may be fabricated with a transparent conductive material (e.g. Indium Tin Oxide (ITO)).

In some exemplary implementations, a plurality of third pixel circuits electrically connected with a plurality of third light emitting elements in the at least one group of light emitting elements may be closer to the first display region than a plurality of first pixel circuits electrically connected with a plurality of first light emitting elements and a plurality of second pixel circuits electrically connected with a plurality of second light emitting elements. For example, the light in the first color may be red light, the light in the second color may be blue light, and the light in the third color light may be green light. In this example, based on an arrangement order of the first type pixel circuits, green light emitting elements are preferred (i.e., the first type pixel circuits connected to the green light emitting elements are preferentially arranged close to the first display region), so that a display defect caused by large differences between the lengths of conductive lines can be alleviated or eliminated.

Solutions of the embodiments will be described below through some examples.

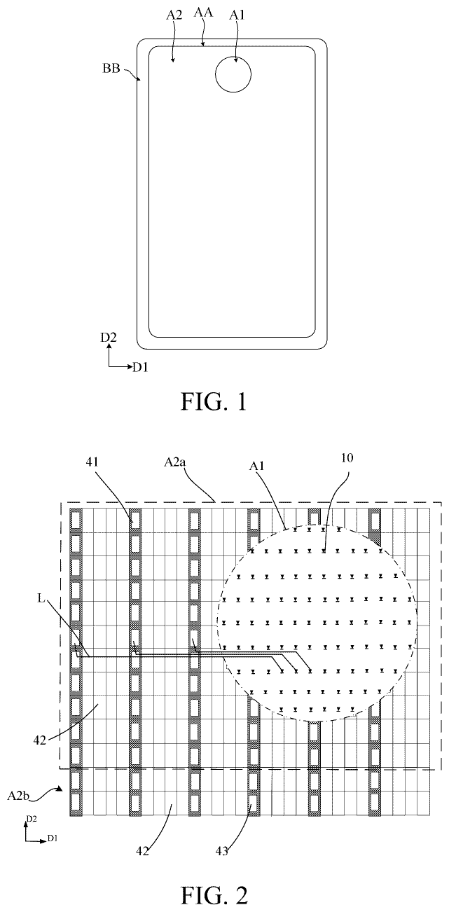

FIG. 1 is a schematic diagram of a display substrate according to at least one embodiment of the present disclosure. In some examples, as shown in FIG. 1, the display substrate may include a display region AA and a peripheral region BB surrounding a periphery of the display region AA. The display region AA of the display substrate may include a first display region A1 and a second display region A2. The second display region A2 may at least partially surround the first display region A1. In this example, the second display region A2 may surround the first display region A1.

In some examples, as shown in FIG. 1, the first display region A1 may be a light-transmitting display region, and may also be referred to as a Full Display with Camera (FDC) region, and the second display region A2 may be a normal display region. For example, an orthographic projection of a photosensitive sensor (such as a camera and other hardware) on the display substrate may be located within the first display region A1 of the display substrate. In some examples, as shown in FIG. 1, the first display region A1 may be circular and a dimension of the orthographic projection of the photosensitive sensor on the display substrate may be smaller than or equal to a dimension of the first display region A1. However, the embodiment is not limited thereto. In other examples, the first display region A1 may be rectangular, and a dimension of the orthographic projection of the photosensitive sensor on the display substrate may be smaller than or equal to a dimension of an inscribed circle of the first display region A1.

In some examples, as shown in FIG. 1, the first display region A1 may be located in a central position at a top of the display region AA. The second display region A2 may surround the first display region A1. However, the embodiment is not limited thereto. For example, the first display region A1 may be located at another position such as an upper left corner or an upper right corner of the display region AA. For example, the second display region A2 may surround at least one side of the first display region A1.

In some examples, as shown in FIG. 1, the display region AA may be in a shape of a rectangle, e.g., a rounded rectangle. The first display region A1 may be circular or elliptical. However, the embodiment is not limited thereto. For example, the first display region A1 may be rectangular, semicircular, pentagonal, or have another shape.

In some examples, the display region AA may be provided with a plurality of sub-pixels. At least one sub-pixel may include a pixel circuit and a light emitting element. The pixel circuit may be configured to drive a connected light emitting element. For example, the pixel circuit is configured to provide a drive current to drive the light emitting element to emit light. The pixel circuit may include a plurality of transistors and at least one capacitor. For example, the pixel circuit may be of a 3T1C, 4T1C, 5T1C, 5T2C, 6T1C, 7T1C, or 8T1C structure. In the above circuit structures, T refers to a thin film transistor, C refers to a capacitor, a number before T represents a quantity of thin film transistors in the circuit, and a number before C represents a quantity of capacitors in the circuit.

In some examples, the plurality of transistors in the pixel circuit may be P type transistors or may be N type transistors. Same type of transistors in the pixel circuit may simplify a process flow, reduce a process difficulty of the display substrate, and improve a yield of a product. In some other examples, the plurality of transistors in the pixel circuit may include P-type transistors and N-type transistors.

In some examples, low temperature poly-silicon thin film transistors, or oxide thin film transistors, or low temperature poly-silicon thin film transistors and oxide thin film transistors may be used as the plurality of transistors in the pixel circuit. Low Temperature Poly Silicon (LTPS) is adopted for an active layer of a low temperature poly silicon thin film transistor and an oxide semiconductor (Oxide) is adopted for an active layer of an oxide thin film transistor. The low temperature poly silicon thin film transistor has advantages such as a high migration rate and fast charging, and the oxide thin film transistor has advantages such as a low leakage current. The low temperature poly silicon thin film transistor and the oxide thin film transistor are integrated on one display panel, that is, an LTPS+Oxide (LTPO for short) display panel, advantages of both the low temperature poly silicon thin film transistor and the oxide thin film transistor may be utilized, so that low-frequency drive may be achieved, power consumption may be reduced, and display quality may be improved.

In some examples, the light emitting element may be any one of a Light Emitting Diode (LED), an Organic Light emitting Diode (OLED), a Quantum dot Light emitting Diode (QLED), a Micro LED (including a mini-LED or a micro-LED) and the like. For example, the light emitting element may be an OLED, and the light emitting element may emit red light, green light, blue light, or white light, etc. under drive of a pixel circuit corresponding to the light emitting element. A color of light emitted by the light emitting element may be determined as required. In some examples, the light emitting element may include an anode, a cathode, and an organic emitting layer located between the anode and the cathode. The anode of the light emitting element may be electrically connected with a corresponding pixel circuit. However, the embodiment is not limited thereto.

In some examples, one pixel unit of the display region AA may include three sub-pixels, and the three sub-pixels may be a red sub-pixel, a green sub-pixel, and a blue sub-pixel, respectively. However, the embodiment is not limited thereto. In some examples, one pixel unit may include four sub-pixels, wherein the four sub-pixels may be a red sub-pixel, a green sub-pixel, a blue sub-pixel, and a white sub-pixel, respectively.

In some examples, a shape of the light emitting element may be a rectangle, a rhombus, a pentagon, or a hexagon. When one pixel unit includes three sub-pixels, light emitting elements of the three sub-pixels may be arranged in a manner to stand side by side horizontally, in a manner to stand side by side vertically, or in a manner like a Chinese character “ [symbol] ”. When one pixel unit includes four sub-pixels, light emitting elements of the four sub-pixels may be arranged in a manner to stand side by side horizontally, in a manner to stand side by side vertically, or in a manner of a square. However, the embodiment is not limited thereto.

FIG. 2 is a partially schematic diagram of a display substrate according to at least one embodiment of the present disclosure. In some examples, as shown in FIG. 2, a second display region A2 of the display substrate may include a transition region A2a and a non-transition region A2b. The transition region A2a may be located on at least one side outside the first display region A1 (for example, on one side; for another example, on both left and right sides; for yet another example, on four sides, i.e., including upper and lower sides, and left and right sides).

In some examples, as shown in FIG. 2, the first display region A1 may include a plurality of first region light emitting elements 10 arranged in an array. The transition region A2a of the second display region A2 may include a plurality of first type pixel circuits 41 and a plurality of second type pixel circuits 42 arranged in an array, and may further include a plurality of second region light emitting elements (not shown). At least one first type pixel circuit 41 in the transition region A2a may be electrically connected to at least one first region light emitting element 10 via a connection line L, and is configured to drive the at least one first region light emitting element 10 to emit light. For example, one first type pixel circuit 41 may be configured to drive two, three or four first region light emitting elements 10 emitting light in a same color to emit light. An orthographic projection of the first region light emitting elements 10 on the base substrate may be not overlapped with an orthographic projection of the first pixel circuit 41 electrically connected thereto on the base substrate. At least one second type pixel circuit 42 in the transition region A2a may be electrically connected to at least one second region light emitting element, and is configured to drive the at least one second region light emitting element to emit light. For example, one second type pixel circuit 42 may be configured to drive one second region light emitting element to emit light. An orthographic projection of the second type pixel circuit 42 may be at least partially overlapped with an orthographic projection of the second region light emitting element electrically connected thereto on the base substrate. In this example, by disposing the first type pixel circuit 41 for driving the first region light emitting element in the transition region A2a, occlusion of light by a pixel circuit may be reduced, thereby increasing a light transmittance of the first display region A1.

In some examples, as shown in FIG. 2, the non-transition region A2b may include a plurality of second type pixel circuits 42 and a plurality of invalid pixel circuits 43 arranged in an array, and may further include a plurality of second region light emitting elements. The transition region A2a may further include a plurality of invalid pixel circuits 43. It may be beneficial to improving uniformity of components of a plurality of film layers in an etching process by providing the invalid pixel circuits 43. For example, a structure of an invalid pixel circuit 43 may be substantially the same as structures of a first type pixel circuit 41 and a second type pixel circuit 42 in a row or column in which the invalid pixel circuit 43 is located, except that the invalid pixel circuit 43 is not electrically connected to any light emitting element.

In some examples, since the second display region A2 is not only provided with the second type pixel circuits 42 electrically connected to the second region light emitting elements, but also provided with the first type pixel circuits 41 electrically connected to the first region light emitting elements 10, a quantity of pixel circuits of the second display region A2 may be greater than a quantity of second region light emitting elements. In some examples, as shown in FIG. 2, a region where newly-added pixel circuits (including the first type pixel circuits and the invalid pixel circuits) are disposed may be obtained by reducing a dimension of the second type pixel circuits in a first direction D1. For example, a dimension of a pixel circuit in the first direction D1 may be smaller than a dimension of the second region light emitting element in the first direction D1. In this example, as shown in FIG. 2, original every a columns of pixel circuits may be compressed along the first direction D1, so that an arrangement space of one column of pixel circuits may be added, and the space occupied by the a columns of pixel circuits before compression and the space occupied by a+1 columns of pixel circuits after compression may be the same. Herein, a may be an integer greater than 1. In some examples, a may be equal to 4. However, the embodiment is not limited thereto. For example, a may be equal to 2 or 3.

In other examples, original b rows of pixel circuits may be compressed along a second direction D2, so that an arrangement space of one row of pixel circuits is added, and the space occupied by the b rows of pixel circuits before compression and the space occupied by b+1 rows of pixel circuits after compression are the same. Herein, b may be an integer greater than 1. Or, a region for disposing a newly-added pixel circuit may be obtained by reducing a dimension of a second type pixel circuit in the first direction D1 and the second direction D2.

In an embodiment of the present disclosure, a group of pixel circuits may include a plurality of pixel circuits sequentially arranged along the first direction. In this example, a group of pixel circuits is a row of pixel circuits, and the row of pixel circuits may all be adjacent to a same gate line (e.g. a scan line). A group of light emitting elements may include a plurality of first region light emitting elements and a plurality of second region light emitting elements arranged in the first direction.

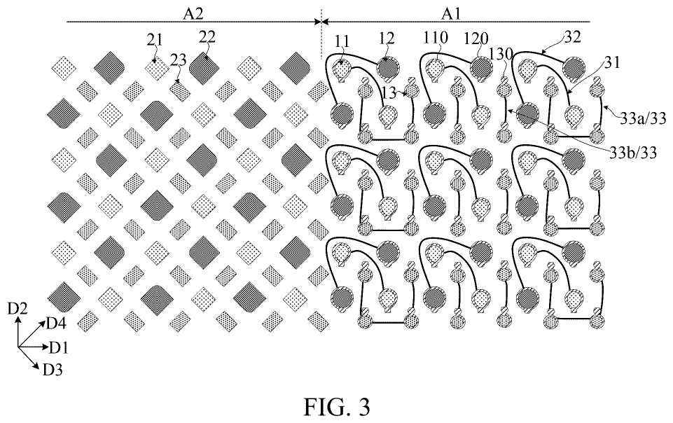

FIG. 3 illustrates schematically a plan view of a part of a display substrate according to at least one embodiment of the present disclosure. In some examples, as shown in FIG. 3, a first display region A1 of the display substrate may include a plurality of first region light emitting elements. The plurality of first region light emitting elements may include a plurality of first light emitting elements 11 emitting light in a first color, a plurality of second light emitting elements 12 emitting light in a second color, and a plurality of third light emitting elements 13 emitting light in a third color. In some examples, the light in the first color may be red light, the light in the second color may be blue light, and the light in the third color may be green light. However, the embodiment is not limited thereto.

In some examples, as shown in FIG. 3, the first light emitting element 11 may include an anode 110, an organic light emitting layer and a cathode. The second light emitting element 12 may include an anode 120, an organic light emitting layer and a cathode. The third light emitting element 13 may include an anode 130, an organic light emitting layer and a cathode. The cathodes of the first light emitting elements 11, the second light emitting elements 12, and the third light emitting elements 13 may be of an integral structure.

In some examples, as shown in FIG. 3, one pixel unit of the first display region A1 may include four first region light emitting elements (e.g. including one first light emitting element 11, one second light emitting element 12 and two third light emitting elements 13). The one first light emitting element 11, one second light emitting element 12, and two third light emitting elements 13 may be arranged in a shape of diamond to form an RGBG pixel arrangement. For example, the first light emitting elements 11 and the second light emitting elements 12 may be arranged at intervals in a same row along a first direction D1, and arranged at intervals in a same column along a second direction D2. The third light emitting elements 13 may be arranged sequentially along a same row along the first direction D1, and arranged sequentially in a same column along the second direction D2. The rows where the first light emitting elements 11 and the second light emitting elements 12 are located are arranged at intervals from the rows where the third light emitting elements 13 are located, and the columns where the first light emitting elements 11 and the second light emitting elements 12 are located are arranged at intervals from the columns where the third light emitting elements 13 are located. The first direction D1 may intersect with the second direction D2. For example, the first direction D1 may be perpendicular to the second direction D2.

In some examples, as shown in FIG. 3, the second display region A2 of the display substrate may include a plurality of second region light emitting elements, the plurality of second region light emitting elements may include a plurality of fourth light emitting elements 21 emitting the light in the first color, a plurality of fifth light emitting elements 22 emitting the light in the second color, and a plurality of sixth light emitting elements 23 emitting the light in the third color. Arrangement of the fourth light emitting elements 21, the fifth light emitting elements 22, and the sixth light emitting elements 23 may be the same as the arrangement of the first light emitting elements 11, the second light emitting elements 12, and the third light emitting elements 13 in the first display region A1, which will not be repeated here.

In some examples, as shown in FIG. 3, an area of a light emitting region of a first region light emitting element may be smaller than an area of a light emitting region of a second region light emitting element that emits light in a same color. Herein, an area of a light emitting region of the first light emitting element 11 may be smaller than an area of a light emitting region of the fourth light emitting element 21. An area of a light emitting region of the second light emitting element 12 may be smaller than an area of a light emitting region of the fifth light emitting elements 22. An area of a light emitting region of the third light emitting element 13 may be smaller than an area of a light emitting region of the sixth light emitting elements 23. For example, the second region light emitting elements may be quadrilateral or pentagonal, and the first region light emitting elements may be circular or elliptical. In this example, the light transmittance of the first display region may be improved and a diffraction condition may be improved by reducing the areas of the light emitting regions of the first region light emitting elements.

In this example, a light emitting region of a light emitting element refers to a stacked region of the anode, the organic light emitting layer and the cathode of the light emitting element, that is, a connection region between the anode exposed by a pixel opening of a pixel definition layer, and the organic light emitting layer as well as the cathode.

In some examples, as shown in FIG. 3, the first display region A1 may further be provided with a plurality of first connection lines 31, a plurality of second connection lines 32 and a plurality of third connection lines 33. In this example, m1 may be 2. One first connection line 31 may be configured to be electrically connected with anodes 110 of two third light emitting elements 11. The two first light emitting elements 11 electrically connected by the first connection line 31 may be located in different rows, and the two first light emitting elements 11 are spaced apart by a third light emitting element 13 in a third direction D3. The third direction D3 intersects with both the first direction D1 and the second direction D2.

In some examples, as shown in FIG. 3, m2 may be 2. One second connection line 32 may be configured to be electrically connected with anodes 120 of two third light emitting elements 12. The two second light emitting elements 12 electrically connected by the second connection line 32 may be located in different rows, and the two second light emitting elements 12 are spaced apart by one first light emitting element 13 in a fourth direction D4. An orthographic projection of the second connection line 32 on the base substrate may be V-shaped. One first light emitting element 11 may be located within a V-shape formed by the second connection line 32. The fourth direction D4 intersects with both the first direction D1 and the second direction D2. For example, the fourth direction D4 may be perpendicular to the third direction D3. The two first light emitting elements 11 electrically connected by the first connection line 31 and the two second light emitting elements 12 electrically connected by the second connection line 32 may be arranged in a 2×2 array, the two first light emitting elements 11 are arranged diagonally, and the two second light emitting elements 12 are arranged diagonally.

In some examples, as shown in FIG. 3, n1 may be 2, and n2 may be 4. Or, n1 may be 4, and n2 may be 2. One third connection line 33 may be electrically connected to anodes 110 of two or four first light emitting elements 11. The plurality of first connection lines 33 may include a plurality of first type third connection lines 33a and a plurality of second type third connection lines 33b. The first type third connection line 33a may be configured to electrically connect four adjacent third light emitting elements 13, and the second type third connection line 33b may be configured to electrically connect two adjacent third light emitting elements 13. The first type first connection line 33a may electrically connect four third light emitting elements 13 arranged in a 2×2 array, and an orthographic projection of the first type first connection line 33a on the base substrate may be U-shaped. A U-shape formed by the first type third connection line 33a may partially surround one first light emitting element 11 or one second light emitting element 12. The second type third connection line 33b may electrically connect two adjacent third light emitting elements 13 arranged along the second direction D2, and an orthographic projection of the second type third connection line 33b on the base substrate may be I-shaped. Four third light emitting elements 13 electrically connected by the first type third connection line 33a may be a first light emitting unit, and two third light emitting elements 13 electrically connected by the second type third connection line 33b may be a second light emitting unit. In the first direction D1, a periodical arrangement of the first light emitting units and the second light emitting units may be in an order of a first light emitting unit, a second light emitting unit, a second light emitting unit, and a first light emitting unit.

In some examples, as shown in FIG. 3, the first connection line 11, the second connection line 12 and the third connection line 13 may be of a same layer structure. Orthographic projections of the first connection line 11, the second connection line 12, and the third connection line 13 on the base substrate may be not overlapped with each other.

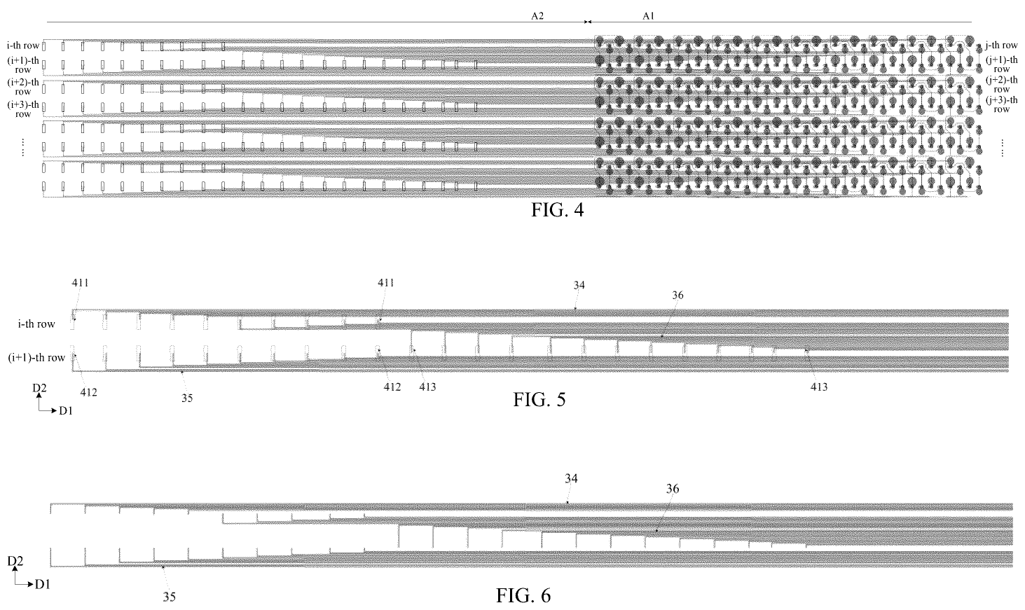

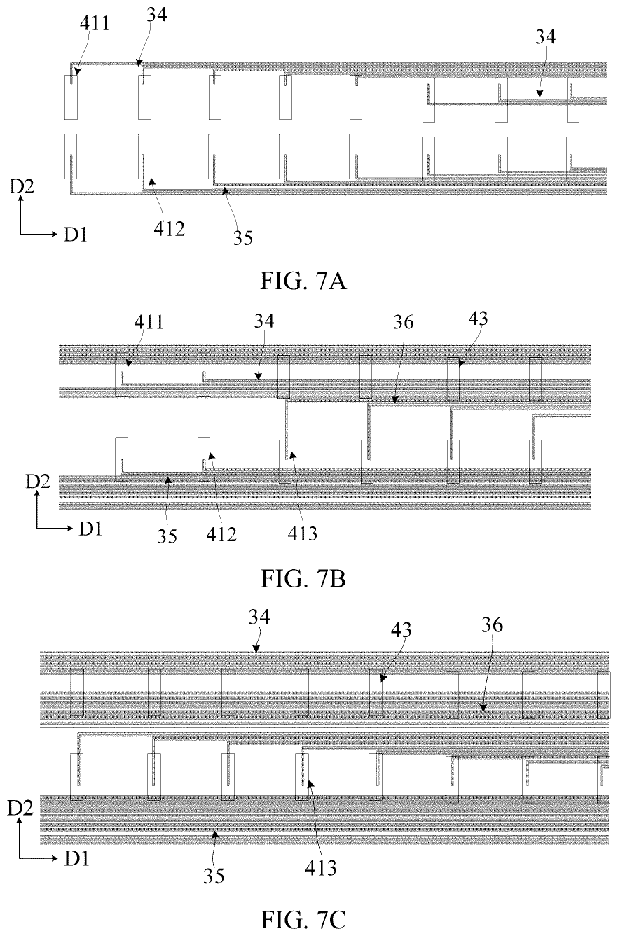

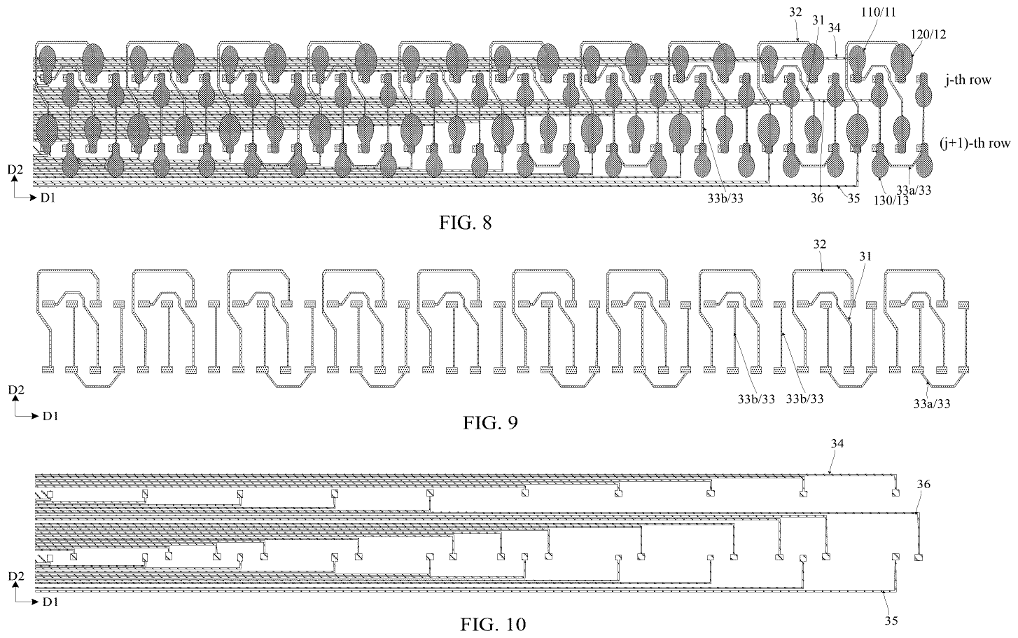

FIG. 4 illustrates schematically a wiring connection diagram of a display substrate according to at least one embodiment of the present disclosure. In FIG. 4, a plurality of rows of first region light emitting elements (for example, from a j-th row to a (j+3)-th row), a first connection line 31, a second connection line 32, and a third connection line 33 located in a first display region A1, a first conductive line 34, a second conductive line 35, and a third conductive line 36 extending from the first display region A1 to a second display region A2, and a plurality of rows of first region pixel circuits (for example, from an i-th row to an (i+3)-th row) located in the second display region A2 are illustrated. FIG. 5 is a partially schematic diagram of a second display region according to at least one embodiment of the present disclosure. FIG. 6 illustrates schematically a partially wiring diagram of a second display region according to at least one embodiment of the present disclosure. Two rows of first type pixel circuits (e.g. an i-th row and an (i+1)-th row), a plurality of first conductive lines 34, second conductive lines 35, and third conductive lines 36 located in the second display region A2 are illustrated in FIG. 5. FIGS. 7A to 7C are partially schematic diagrams in FIG. 5. FIG. 8 is a partially schematic diagram of a first display region according to at least one embodiment of the present disclosure. FIGS. 9 and 10 illustrate schematically a partial wiring diagram of a first display region according to at least one embodiment of the present disclosure. Two rows of first region light emitting elements (e.g. a j-th row and a (j+1)-th row), a plurality of first connection lines 31, second connection lines 32, third connection lines 33, first conductive lines 34, second conductive lines 35, and third conductive lines 36 located in the first display region A1 are illustrated in FIG. 8. FIG. 9 is a schematic diagram of a plurality of first connection lines 31, second connection lines 32, and third connection lines 33 in FIG. 8. FIG. 10 is a schematic diagram of a plurality of first conductive lines 34, second conductive lines 35, and third conductive lines 36 in FIG. 8.

In some examples, as shown in FIGS. 4 to 10, the plurality of first type pixel circuits may include a plurality of first pixel circuits 411, a plurality of second pixel circuits 412, and a plurality of third pixel circuits 413. At least one first pixel circuit 411 may be electrically connected to anodes 110 of two first light emitting elements 11 through a first conductive line 34 and a first connection line 31, and at least one second pixel circuit 412 may be electrically connected to anodes 120 of two second light emitting elements 12 through a second conductive line 35 and a second connection line 32. At least one third pixel circuit 413 may be electrically connected to anodes 130 of four third light emitting elements 13 through a third conductive line 36 and a third connection line 33a, and at least one third pixel circuit 413 may be electrically connected to anodes 130 of two third light emitting elements 13 through a third conductive line 36 and a third connection line 33b.

In some examples, as shown in FIGS. 4 to 10, a first pixel circuit 411 electrically connected to a first light emitting element 11 in the j-th row in first region light emitting elements through a first conductive line 34 may be located in the i-th row of pixel circuits, and electrically connected to an anode 110 of a first light emitting element 11 in the (j+1)-th row through a first connection line 31. A second light emitting element 12 in the j-th row in first region light emitting elements may be electrically connected to a second light emitting element 12 in the (j+1)-th row through a second connection line 32, and electrically connected to a second pixel circuit 412 located in the (i+1)-th row of pixel circuits through a second conductive line 35. A third light emitting element 13 in the j-th row in first region light emitting elements may be electrically connected to a third light emitting element 13 in the (j+1)-th row through a third connection line 33, and electrically connected to a third pixel circuit 413 located in the (i+1)-th row of pixel circuits through a third conductive line 36. In this example, the first pixel circuit 411 electrically connected to the first light emitting element 11 in the j row and the second pixel circuit 412 electrically connected to the second light emitting element 12 are located in different rows, for example, may be in adjacent rows, and the second pixel circuit 412 electrically connected to the second light emitting element 12 in the j row and the third pixel circuit 413 electrically connected to the third light emitting element 13 are located in a same row.

In this example, the first type pixel circuits electrically connected to the light emitting elements emitting light in different colors in the first region light emitting elements in the same row may be located in different rows, which is beneficial to shortening a length of conductive lines (e.g. the first conductive line to the third conductive line) connecting the first region light emitting elements and the first type pixel circuits, thereby facilitating reducing a difference between loads of different conductive lines, reducing a difference between brightness in the first display region and in the second display region, and further improving the display effect of the display substrate. In other examples, pixel circuits electrically connected with the first, second, and third light emitting elements of first region light emitting elements in a same row may be located in different rows. For example, one row of first region light emitting elements may correspond to three rows of first type pixel circuits. Or, a first pixel circuit electrically connected with a first light emitting element and a first pixel circuit electrically connected with a third light emitting element, of first region light emitting elements in a same row may be located in a same row, while a second pixel circuit electrically connected with a second light emitting element and the first pixel circuit electrically connected with the first light emitting element may be located in different rows.

In some examples, as shown in FIGS. 4 to 10, in any row of first region light emitting elements, a third pixel circuit 413 electrically connected with a third light emitting element 13 is closer to the first display region than a first pixel circuit 411 electrically connected with a first light emitting element 11 and a second pixel circuit 412 electrically connected with the second light emitting element 12. In other words, in this example, in any row of first region light emitting elements, the third light emitting element 13 is preferentially electrically connected to a first type pixel circuit close to the first display region. In this way, a difference between lengths of third conductive lines electrically connected to the third light emitting elements may be reduced, reducing or avoiding the display defect.

In some examples, as shown in FIGS. 4 to 10, a plurality of first conductive lines 34 electrically connected to a plurality of first light emitting elements 11 in the j-th row may be located on opposite sides of the i-th row of pixel circuits in the second direction D2. A plurality of second conductive lines 35 electrically connected to a plurality of second light emitting elements 12 in the j-th row may be located on a side of the (i+1)-th row of pixel circuits away from the i-th row of pixel circuits in the second direction D2. A plurality of third conductive lines 36 electrically connected to a plurality of third light emitting elements 13 in the j-th row may be located on a side of the (i+1)-th row of pixel circuits close to the i-th row of pixel circuits in the second direction D2. However, the embodiment is not limited thereto. For example, a plurality of first conductive lines 34 electrically connected to a plurality of first light emitting elements 11 in the j-th row may be located on a side of the i-th row of pixel circuits away from the (i+1)-th row of pixel circuits in the second direction D2. The arrangement of the first conductive lines, the second conductive lines and the third conductive lines in this example is beneficial to arrangement of traces and saves arrangement space of the traces.

In some examples, as shown in FIGS. 4 to 10, a plurality of first pixel circuits 411 electrically connected with a plurality of first light emitting elements in the j-th row may be continuously arranged in the i-th row of pixel circuits. For example, only a second type pixel circuit may be arranged between adjacent first pixel circuits 411, without other first type pixel circuits. A plurality of second pixel circuits 412 electrically connected with a plurality of first light emitting elements in the j-th row may be continuously arranged in the (i+1)-th row of pixel circuits. For example, only a second type pixel circuit may be arranged between adjacent second pixel circuits 412, without other first type pixel circuits. A plurality of third pixel circuits 413 electrically connected with a plurality of third light emitting elements in the j-th row may be continuously arranged in the (i+1)-th row of pixel circuits. For example, only a second type pixel circuit may be arranged between adjacent third pixel circuits 413, without other first type pixel circuits.

In some examples, as shown in FIGS. 4 to 10, at least one first pixel circuit 411 electrically connected with the first light emitting elements 11 of the j-th row may be in a same column as at least one second pixel circuit 412 electrically connected with the second light emitting elements 12 of the j-th row. As shown in FIG. 5, a plurality of first pixel circuits 411 of the i-th row may be in a one-to-one correspondence with a plurality of second pixel circuits 412 of the (i+1)-th row, and a first pixel circuit 411 may be located in a same column as a corresponding second pixel circuit 412. A third pixel circuit 413 may be in a same column as an invalid pixel circuit 43.

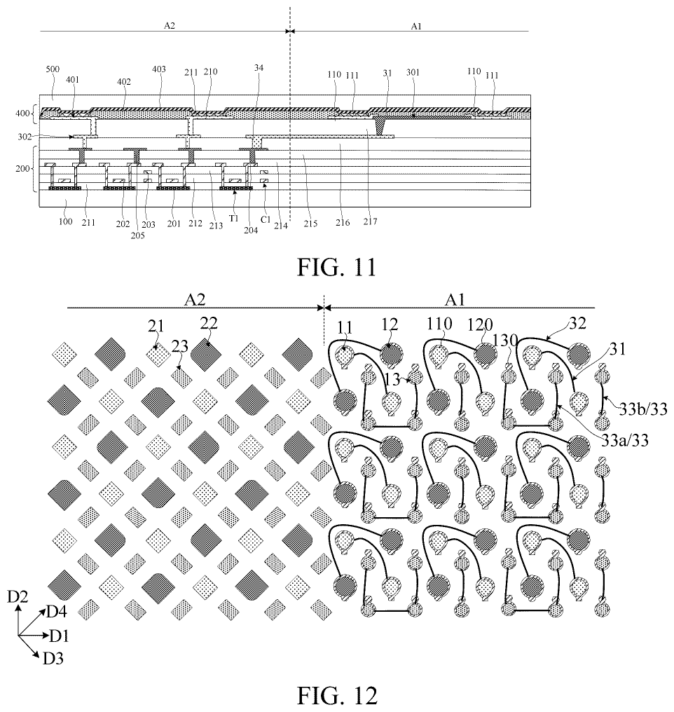

FIG. 11 illustrates schematically a sectional view of a part of a display substrate according to at least one embodiment of the present disclosure. In some examples, as shown in FIG. 11, in a direction perpendicular to the display substrate, a second display region A2 may include a base substrate 100, and a circuit structure layer 200, a second transparent conductive layer 302, a first transparent conductive layer 301, a light emitting structure layer 400 and an encapsulation structure layer 500 which are sequentially arranged on the base substrate 100. A first display region A1 may include a base substrate 100, and a composite insulation layer, a second transparent conductive layer 302, a light emitting structure layer 400, and an encapsulation structure layer 500 which are sequentially arranged on the base substrate 100. The circuit structure layer 200 of the second display region A2 may include a semiconductor layer 201, a first insulation layer 211, a first gate metal layer 202, a second insulation layer 212, a second gate metal layer 203, a third insulation layer 213, a first source-drain metal layer 204, a fourth insulation layer 214, a fifth insulation layer 215, and a second source-drain metal layer 205 which are sequentially arranged on the base substrate 100. A sixth insulation layer 216 is provided between the circuit structure layer 200 and the second transparent conductive layer 302. A seventh insulation layer 217 may be provided between the second transparent conductive layer 302 and the first transparent conductive layer 301. The composite insulation layer of the first display region A1 may include the first insulation layer 211, the second insulation layer 212, the third insulation layer 213, the fourth insulation layer 214, the fifth insulation layer 215, and the sixth insulation layer 216 which are stacked sequentially.

In some examples, the first insulation layer 211 to the fourth insulation layer 214 may all be inorganic insulation layers, and the fifth insulation layer 215 to the seventh insulation layer 217 may all be organic insulation layers. The fifth insulation layer 215 to the seventh insulation layer 217 may also be referred to as planarization layers. However, the embodiment is not limited thereto. In some other examples, only the fifth insulation layer may be disposed between the first source-drain metal layer 204 and the second source-drain metal layer 205.

In some examples, as shown in FIG. 11, the light emitting structure layer 400 may include an anode layer 401, a pixel definition layer 402, an organic light emitting layer, and a cathode layer 403 which are sequentially arranged on the base substrate 100. The anode layer 401 may be electrically connected to pixel circuits of the circuit structure layer 200, the organic light emitting layer may be connected to the anode layer 401, and the cathode layer 403 may be connected to the organic light emitting layer. The organic light emitting layer may be driven by the anode layer 401 and the cathode layer 403 to emit light in a corresponding color. The encapsulation structure layer 500 may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer may be disposed between the first encapsulation layer and the third encapsulation layer to form a stacked structure of inorganic material/organic material/inorganic material, which may ensure that external moisture cannot enter the light emitting structure layer. In some possible implementations, the display substrate may further include other film layers, such as a touch structure layer, a color filter layer, or the like, which is not limited here in the present disclosure.

Exemplary description is made below for a structure and a manufacturing process of a display substrate. A “patterning process” mentioned in the embodiments of the present disclosure includes a treatment such as photoresist coating, mask exposure, development, etching, and photoresist stripping for a metal material, an inorganic material, or a transparent conductive material, and includes a treatment such as organic material coating, mask exposure, and development for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a material on a base substrate by using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are of a same layer structure” or “A and B are disposed in a same layer” mentioned in the embodiments of the present disclosure means that A and B are formed simultaneously through a same patterning process, or surfaces of A and B close to a base substrate have basically a same distance from the base substrate, or the surfaces of A and B close to the base substrate are in direct contact with a same film layer. A “thickness” of a film layer is a dimension of the film layer in a direction perpendicular to the display substrate. In an exemplary implementation of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.

In some exemplary implementations, a manufacturing process of the display substrate may include following operations.

(1) A base substrate is provided. In some examples, the base substrate 100 may be a rigid substrate, or may be a flexible substrate. For example, the rigid base substrate may be made of, but not limited to, one or more of glass and quartz. The flexible base substrate may be made of, but not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers. In some examples, the flexible base may include a first flexible material layer, a first inorganic material layer, a second flexible material layer and a second inorganic material layer which are stacked. The first flexible material layer and the second flexible material layer may be made of a material such as polyimide (PI), polyethylene terephthalate (PET), or a polymer soft film on which surface treatment is performed, and a material of the first inorganic material layer and the second inorganic material layer may be silicon nitride (SiNx) or silicon oxide (SiOx), etc., which are used to improve resistance to water and oxygen of the base.

(2) A semiconductor layer is formed. In some examples, a semiconductor thin film is deposited on the base substrate 100, and the semiconductor thin film is patterned through a patterning process to form a semiconductor layer 201 in a second region A2. In some examples, a material of the semiconductor layer 201 may be amorphous Silicon (a-Si), polycrystalline Silicon (p-Si), hexathiophene, polythiophene, or other materials.

In some examples, the semiconductor layer 201 of the second display region A2 may include active layers of a plurality of transistors of a plurality of pixel circuits (e.g. an active layer of a first transistor T1). An active layer of a transistor may include a first region, a second region, and a channel region located between the first region and the second region. In some examples, the first region and the second region of the active layer may be interpreted as a source electrode or a drain electrode of a transistor. A part of the active layer between the transistors may be interpreted as a trace doped with impurities, and may be used for electrically connecting the transistors. The channel region may not be doped with impurities, and has characteristics of a semiconductor. The first region and the second region located on two sides of the channel region may be doped with impurities and thus have electrical conductivity. The impurities may be changed according to a type of a transistor. However, the embodiment is not limited thereto.

(3) A first gate metal layer is formed. In some examples, a first insulation thin film and a first conductive thin film are sequentially deposited on the base substrate 100 where the aforementioned structure is formed, and the first conductive thin film is patterned through a patterning process to form a first insulation layer 211 covering the semiconductor layer 201, and a first gate metal layer 202 disposed on the first insulation layer 211 in the second display region A2. In some examples, the first gate metal layer 202 may include gate electrodes of transistors and one plate of each of storage capacitors of a plurality of pixel circuits (e.g., including a gate electrode of the first transistor T1, a first plate of a first capacitor C1).

(4) A second gate metal layer is formed. In some examples, a second insulation thin film and a second conductive thin film are sequentially deposited on the base substrate 100 where the aforementioned structures are formed, the second conductive thin film is patterned through a patterning process to form a second insulation layer 212, and a second gate metal layer 203 disposed on the second insulation layer 212 in the second display region A2. In some examples, the second gate metal layer 203 may include another plate of each of storage capacitors of a plurality of pixel circuits (e.g. including a second plate of the first capacitor C1).

(5) A first source-drain metal layer is formed. In some examples, a third insulation thin film is deposited on the base substrate 100 where the aforementioned patterns are formed, and the third insulation thin film is patterned through a patterning process to form a third insulation layer 213. The third insulation layer 213 of the second display region A2 may be provided with a plurality of vias, which may expose, for example, surfaces of the semiconductor layer 201, the first gate metal layer 202, and the second gate metal layer 203, respectively. Subsequently, a third conductive thin film is deposited and patterned through a patterning process to form a first source-drain metal layer 204 on the third insulation layer 213 of the second display region A2. In some examples, the first source-drain metal layer 204 may include first electrodes and second electrodes of transistors of a plurality of pixel circuits (e.g. including a first electrode and a second electrode of the first transistor T1).

(6) A second source-drain metal layer is formed. In some examples, a fourth insulation thin film is deposited on the base substrate 100 where the aforementioned patterns are formed to form a fourth insulation layer 214. Subsequently, a fifth insulation thin film is coated and patterned through a patterning process to form a fifth insulation layer 215. In some examples, after a via or groove is formed in the fifth insulation layer 215, the fourth insulation layer 214 may be etched to form a via or groove provided in the fourth insulation layer 214 to expose a surface of the first source-drain metal layer 204. Subsequently, a fourth conductive thin film is deposited and patterned through a patterning process to form a second source-drain metal layer 205 on the fifth insulation layer 215 of the second display region A2. In some examples, the second source-drain metal layer 205 may include a plurality of first anode connection electrodes. The first anode connection electrodes may be configured to be electrically connected to a first pixel circuits or a second pixel circuit.

(7) A second transparent conductive layer is formed. In some examples, a sixth insulation thin film is coated on the base substrate 100 where the aforementioned patterns are formed, and the sixth insulation thin film is patterned through a patterning process to form a sixth insulation layer 216. Subsequently, a second transparent conductive thin film is deposited and patterned through a patterning process to form a second transparent conductive layer 302. In some examples, the second transparent conductive layer 302 may include a plurality of second anode connection electrodes, and a plurality of first conductive lines 34, a plurality of second conductive lines, and a plurality of third conductive lines, which are located in the second display region A2. A second anode connection electrode may be electrically connected to a first anode connection electrode electrically connected to a second type pixel circuit. A first conductive line 31, a second conductive line, and a third conductive line may be electrically connected to a first anode connection electrode electrically connected to a first type pixel circuit. The first conductive line 31, the second conductive line, and the third conductive line may extend from the second display region A2 to the first display region A1.

(8) A first transparent conductive layer is formed. In some examples, a seventh insulation thin film is coated on the base substrate 100 where the aforementioned patterns are formed, and the seventh insulation thin film is patterned through a patterning process to form a seventh insulation layer 217. Subsequently, a first transparent conductive thin film is deposited and patterned through a patterning process to form a first transparent conductive layer 301 in the first display region A1. In some examples, the first transparent conductive layer 301 may include a plurality of first connection lines 31, a plurality of second connection lines, and a plurality of third connection lines.

(9) An anode layer, a pixel definition layer, an organic light emitting layer, a cathode layer and an encapsulation structure layer are formed in sequence. In some examples, an anode thin film is deposited on the base substrate 100 where the aforementioned patterns are formed, and the anode thin film is patterned through a patterning process to form an anode layer 401. For example, the anode layer 401 may include an anode 210 of a fourth light emitting element located in the second display region A2 and an anode 110 of a first light emitting element located in the first display region A1. There may be no insulation layer between the anode layer 210 and the first transparent conductive layer 301 of the first display region A1. The first connection line 31 of the first transparent conductive layer 301 may be in direct contact with the anode 110 of the first light emitting element. A first connection line 31 electrically connected with an anode 110 of a first light emitting element may be electrically connected to a first conductive line 34 through a via opened in the seventh insulation layer 217 to achieve an electrical connection with a first pixel circuit of the second display region A2. An anode 210 of a fourth light emitting element may be electrically connected to a second anode connection electrode through a via opened in the seventh insulation layer 217 to achieve an electrical connection with a second type pixel circuit. However, the embodiment is not limited thereto. In some other examples, an anode of a first light emitting element may be electrically connected to the first conductive line 34 through a via opened in the seventh insulation layer 217.

Subsequently, a pixel definition thin film is coated on the base substrate 100 where the aforementioned patterns are formed, and a pixel definition layer 402 is formed through mask, exposure, and development processes. The pixel definition layer may be formed with a plurality of pixel openings exposing the anode layer. Subsequently, an organic light emitting layer is formed within the pixel openings formed. For example, an organic light emitting layer 211 of a fourth light emitting element of the second display region A2 is connected to an anode 210, and an organic light emitting layer 111 of a first light emitting element of the first display region A1 is connected to an anode 110. Subsequently, a cathode thin film is deposited, the cathode thin film is patterned through a patterning process to form a cathode layer 403, and the cathode layer 403 is electrically connected to the organic emitting layer and a second power supply line, respectively. In some examples, an encapsulation structure layer 500 is formed on the cathode layer 403. The encapsulation structure layer 500 may include a stacked structure of inorganic material/organic material/inorganic material.

In some exemplary implementations, the first gate metal layer 202, the second gate metal layer 203, the first source-drain metal layer 204 and the second source-drain metal layer 205 may be made of metal materials, such as any one or more of silver (Ag), copper (Cu), aluminum (Al) and molybdenum (Mo), or alloy materials of the above-mentioned metals, such as aluminum neodymium alloy (AlNd) or molybdenum niobium alloy (MoNb), and may be a single-layer structure or a multi-layer composite structure such as Mo/Cu/Mo. The first insulation layer 211, the second insulation layer 212, the third insulation layer 213, and the fourth insulation layer 214 may be made of any one or more of Silicon Oxide (SiOx), Silicon Nitride (SiNx), and Silicon Oxynitride (SiON), and may be a single layer, a multiple-layer, or a composite layer. The first insulation layer 211 and the second insulation layer 212 may be referred to as Gate Insulation (GI) layers, the third insulation layer 213 may be referred to as an Interlayer Dielectric (ILD) layer, and the fourth insulation layer 214 may be referred to as a passivation layer. The fifth insulation 215, the sixth insulation layer 216, and the seventh insulation layer 217 may be made of an organic material, such as polyimide, acrylic, or polyethylene terephthalate. The pixel definition layer 402 may be made of an organic material, such as polyimide, acrylic, or polyethylene terephthalate. The anode layer 401 may be made of a reflective material such as a metal, and the cathode layer 403 may be made of a transparent conductive material. However, the embodiment is not limited thereto.

The structure and the manufacturing process of the display substrate according to the embodiments of the present disclosure are described only as an example. In some exemplary implementations, a corresponding structure may be changed and a patterning process may be added or removed according to actual needs. For example, the display substrate may not include a second source-drain metal layer. However, the embodiments of the present disclosure are not limited thereto.

In the manufacturing process of the display substrate according to the embodiment, the first transparent conductive layer, the second transparent conductive layer and the seventh insulation layer are provided, which may achieve the electrical connection between the first type pixel circuits and the first region light emitting elements. Compared with a manufacturing solution by using three transparent conductive layers and three insulation layers, this example may simplify the manufacturing process, is easy to implement, has high production efficiency, low production cost and high yield.

According to the display substrate provided in the embodiment, first type pixel circuits electrically connected with light emitting elements emitting light in different colors in a row of first region light emitting elements may be located in at least two rows, which can be beneficial to shortening a length of a conductive line connecting a first region light emitting element with a first type pixel circuit, thereby reducing a difference between brightness in the first display region and in the second display region, and improving display effect of the display substrate.

FIG. 12 illustrates schematically a plan view of another part of a display substrate according to at least one embodiment of the present disclosure. In some examples, as shown in FIG. 12, a first display region A1 of the display substrate may include a plurality of first region light emitting elements. The plurality of first region light emitting elements may include a plurality of first light emitting elements 11 emitting light in a first color, a plurality of second light emitting elements 12 emitting light in a second color, and a plurality of third light emitting elements 13 emitting light in a third color. Four third light emitting elements 13 electrically connected by the first type third connection line 33a may be a first light emitting unit, and two third light emitting elements 13 electrically connected by the second type third connection line 33b may be a second light emitting unit. In a first direction D1, the first light emitting units and the second light emitting units are arranged at intervals. With regard to remaining structures of the display substrate in this embodiment, reference may be made to the description of the above-mentioned embodiments, and will not be repeated here.

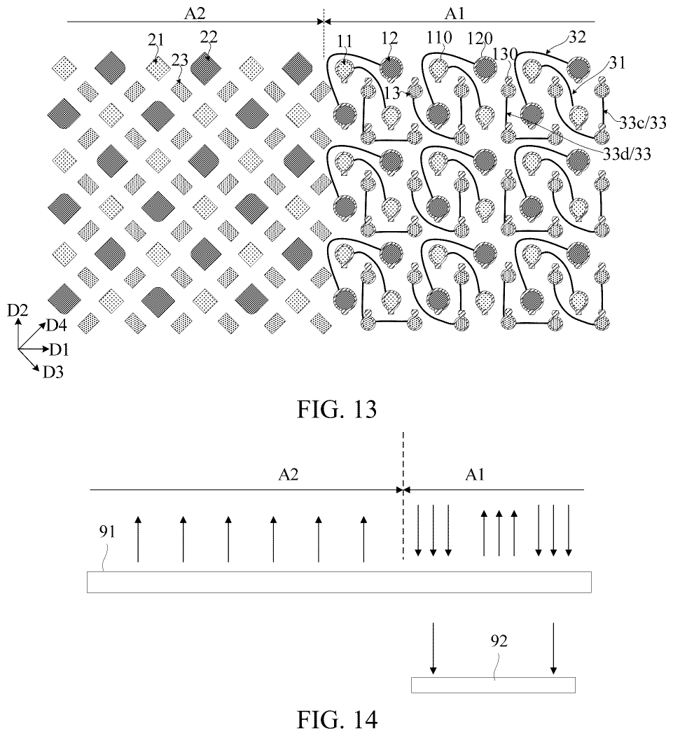

FIG. 13 illustrates schematically another partial plan view of a display substrate according to at least one embodiment of the present disclosure. In some examples, as shown in FIG. 13, a plurality of first region light emitting elements in the first display region A1 may include a plurality of first light emitting elements 11 emitting first color light, a plurality of second light emitting elements 12 emitting second color light, and a plurality of third light emitting elements 13 emitting third color light. Each third connection line 33 may electrically connect three third light emitting elements 13. Three third light emitting elements 13 electrically connected by each third connection line 33 may be arranged in two rows. The plurality of third connection lines 33 may include a plurality of third type third connection lines 33c and a plurality of fourth type third connection lines 33d. Three third light emitting elements 13 electrically connected by a third type third connection line 33c and three first light emitting elements 13 electrically connected by a fourth type first connection line 33d may be arranged in a 2×3 array. A third type third connection line 33c may be configured to electrically connect three adjacent third light emitting elements 13, wherein two third light emitting elements 13 are in a same row and two third light emitting elements 13 are in a same column. The third type third connection line 33c may include two straight segments, one of the straight segments is electrically connected to two third light emitting elements 13 located in a same column, and another one of the straight segments is electrically connected to two third light emitting elements 13 located in a same row. For example, an orthographic projection of a third type third connection line 33c on the base substrate may be L-shaped. A fourth type third connection line 33d may be configured to electrically connect three adjacent third light emitting elements 13, wherein two third light emitting elements 13 are in a same row and two third light emitting elements 13 are in a same column. The fourth type third connection line 33d may include one straight segment and one arc segment, wherein the straight segment electrically connects two first light emitting elements 13 located in a same column, and the arc segment may electrically connect two first light emitting elements 13 not located in a same row or a same column. For example, an orthographic projection of the fourth type third connection line 33d on the base substrate may be similarly V-shaped. For example, first region light emitting elements partially surrounded by a third type third connection line 33c and a fourth type third connection line 33d adjacent to each other may emit light in different colors. For example, a third type third connection line 33c partially surrounds a first light emitting element 11, and an adjacent fourth type third connection line 33d partially surrounds a second light emitting element 12. In the present disclosure, the third type third connection line and the fourth type third connection line adjacent to each other refer to that one first light emitting element electrically connected to the third type third connection line is located in a same column as one first light emitting element electrically connected to the fourth type third connection line. With regard to remaining structures of the display substrate in this embodiment, reference may be made to the description of the above-mentioned embodiments, and will not be repeated here.

In this example, a plurality of first region light emitting elements are driven by one first type pixel circuit, and the first type pixel circuits electrically connected to light emitting elements emitting light in different colors in a row of first region light emitting elements are located in at least two rows, which is beneficial to shortening a length of conductive lines, reducing a difference between brightness in the first display region and in the second display region, thereby ensuring the display image quality, and reducing the quantity of connection lines and the product cost.

A display apparatus is also provided in an embodiment of the present disclosure, which includes the aforementioned display substrate.

FIG. 14 is a schematic diagram of a display apparatus according to at least one embodiment of the present disclosure. As shown in FIG. 14, the display apparatus provided in this embodiment includes a display substrate 91, and a photosensitive sensor 92 located away from a light-emitting side of a display structure layer of the display substrate 91. An orthographic projection of the photosensitive sensor 92 on the display substrate 91 is overlapped with the first display region A1.

In some examples, the display substrate 91 may be a flexible OLED display substrate, a QLED display substrate, a Micro-LED display substrate, or a Mini-LED display substrate. The display apparatus may be any product or component with a display function such as an OLED display, a cell phone, a tablet, a television, a display, a laptop, a digital photo frame, and a navigator, which is not limited in the embodiments of the present disclosure.

The drawings of the present disclosure only involve structures involved in the present disclosure, and other structures may refer to conventional designs. The embodiments of the present disclosure, i.e., features in the embodiments, may be combined with each other to obtain new embodiments if there is no conflict. Those of ordinary skills in the art should understand that modifications or equivalent replacements may be made to the technical solutions of the present disclosure without departing from the essence and scope of the technical solutions of the present disclosure, and shall all fall within the scope of the claims of the present disclosure.

1. A display substrate, comprising:
a base substrate, comprising a first display region and a second display region located on at least one side of the first display region;
a plurality of light emitting elements located in the first display region and the second display region, wherein the plurality of light emitting elements comprise a plurality of groups of light emitting elements, each group of light emitting elements is arranged along a first direction, the plurality of groups of light emitting elements are arranged along a second direction, at least one group of light emitting elements in the plurality of groups of light emitting elements comprises a plurality of first region light emitting elements and a plurality of second region light emitting elements, the plurality of first region light emitting elements are located in the first display region, and the plurality of second region light emitting elements are located in the second display region;
a plurality of pixel circuits located in the second display region, wherein the plurality of pixel circuits comprise a plurality of groups of pixel circuits, each group of pixel circuits is arranged along the first direction, the plurality of groups of pixel circuits are arranged along the second direction, at least one group of pixel circuits in the plurality of groups of pixel circuits comprises a plurality of first type pixel circuits and a plurality of second type pixel circuits, the plurality of first type pixel circuits are arranged at intervals between the plurality of second type pixel circuits;
wherein at least one first type pixel circuit in the plurality of first type pixel circuits is electrically connected to at least one first region light emitting element in the plurality of first region light emitting elements, and at least one second type pixel circuit in the plurality of second type pixel circuits is electrically connected to at least one second region light emitting element in the plurality of second region light emitting elements;
the plurality of first region light emitting elements at least comprise a plurality of first light emitting elements emitting light in a first color and a plurality of second light emitting elements emitting light in a second color; the plurality of first type pixel circuits at least comprise a plurality of first pixel circuits and a plurality of second pixel circuits; the plurality of first light emitting elements are electrically connected to the plurality of first pixel circuits through a plurality of first conductive lines, and the plurality of second light emitting elements are electrically connected to the plurality of second pixel circuits through a plurality of second conductive lines;
a plurality of first pixel circuits electrically connected to a plurality of first light emitting elements in the at least one group of light emitting elements and a plurality of second pixel circuits electrically connected to a plurality of second light emitting elements in the at least one group of light emitting elements are located in different groups of pixel circuits; the first direction intersects with the second direction.

2. The display substrate of claim 1, wherein a pixel circuit group where the plurality of first pixel circuits electrically connected to the plurality of first light emitting elements in the at least one group of light emitting elements are located is adjacent to a pixel circuit group where the plurality of second pixel circuits electrically connected to the plurality of second light emitting elements in the at least one group of light emitting elements are located, in the second direction.

3. The display substrate of claim 1, wherein the plurality of first region light emitting elements further comprise a plurality of third light emitting elements emitting light in a third color; the plurality of first type pixel circuits further comprise a plurality of third pixel circuits, wherein the plurality of third light emitting elements are electrically connected to the plurality of third pixel circuits through a plurality of third conductive lines;
a plurality of third pixel circuits electrically connected to a plurality of third light emitting elements in the at least one group of light emitting elements and a plurality of first pixel circuits electrically connected to a plurality of first light emitting elements in the at least one group of light emitting elements are located in a same group of pixel circuits; or, a plurality of third pixel circuits electrically connected to a plurality of third light emitting elements in the at least one group of light emitting elements and a plurality of second pixel circuits electrically connected to a plurality of second light emitting elements in the at least one group of light emitting elements are located in a same group of pixel circuits.

4. The display substrate of claim 3, wherein the first conductive lines, the second conductive lines, and the third conductive lines are of a same layer structure.

5. The display substrate of claim 3, wherein a plurality of third pixel circuits electrically connected to a plurality of third light emitting elements in the at least one group of light emitting elements are closer to the first display region than a plurality of first pixel circuits electrically connected to a plurality of first light emitting elements and a plurality of second pixel circuits electrically connected to a plurality of second light emitting elements in the at least one group of light emitting elements.

6. The display substrate of claim 3, wherein the at least one third pixel circuit is electrically connected to n1 third light emitting elements and configured to drive the n1 third light emitting elements to emit light, and the at least one third pixel circuit is electrically connected to n2 third light emitting elements and configured to drive the n2 third light emitting elements to emit light, where both n1 and n2 are integers greater than or equal to 2 and n1 is different from n2.

7. The display substrate of claim 6, wherein the n1 third light emitting elements serve as first light emitting units, and the n2 third light emitting elements serve as second light emitting units, the first light emitting units and the second light emitting units are arranged at intervals along the first direction or periodically in an order of a first light emitting unit, a second light emitting unit, a second light emitting unit and a first light emitting unit.

8. The display substrate of claim 6, further comprising: a plurality of third connection lines located in the first display region, wherein the n1 third light emitting elements or the n2 third light emitting elements are electrically connected by one third connection line.

9. The display substrate of claim 3, wherein the plurality of third conductive lines electrically connected to the plurality of third pixel circuits and the plurality of first conductive lines electrically connected to the plurality of first pixel circuits, which are located in a same group of pixel circuits, are located on opposite sides of the group of pixel circuits in the second direction; or, the plurality of third conductive lines electrically connected to the plurality of third pixel circuits and the plurality of second conductive lines electrically connected to the plurality of second pixel circuits, which are located in a same group of pixel circuits, are located on opposite sides of the group of pixel circuits in the second direction.

10. The display substrate of claim 3, wherein the light in the first color is red light, the light in the second color is blue light, and the light in the third color is green light.

11. The display substrate of claim 1, wherein at least one first pixel circuit of the plurality of first pixel circuits is electrically connected to m1 first light emitting elements and is configured to drive the m1 first light emitting elements to emit light; at least one second pixel circuit of the plurality of second pixel circuits is electrically connected to m2 second light emitting elements and is configured to drive the m2 second light emitting elements to emit light, wherein both m1 and n2 are integers greater than or equal to 2.

12. A display apparatus, comprising the display substrate according to claim 1.

13. The display substrate of claim 2, wherein the plurality of first region light emitting elements further comprise a plurality of third light emitting elements emitting light in a third color; the plurality of first type pixel circuits further comprise a plurality of third pixel circuits, wherein the plurality of third light emitting elements are electrically connected to the plurality of third pixel circuits through a plurality of third conductive lines;
a plurality of third pixel circuits electrically connected to a plurality of third light emitting elements in the at least one group of light emitting elements and a plurality of first pixel circuits electrically connected to a plurality of first light emitting elements in the at least one group of light emitting elements are located in a same group of pixel circuits; or, a plurality of third pixel circuits electrically connected to a plurality of third light emitting elements in the at least one group of light emitting elements and a plurality of second pixel circuits electrically connected to a plurality of second light emitting elements in the at least one group of light emitting elements are located in a same group of pixel circuits.

14. The display substrate of claim 4, wherein a plurality of third pixel circuits electrically connected to a plurality of third light emitting elements in the at least one group of light emitting elements are closer to the first display region than a plurality of first pixel circuits electrically connected to a plurality of first light emitting elements and a plurality of second pixel circuits electrically connected to a plurality of second light emitting elements in the at least one group of light emitting elements.

15. The display substrate of claim 4, wherein the at least one third pixel circuit is electrically connected to n1 third light emitting elements and configured to drive the n1 third light emitting elements to emit light, and the at least one third pixel circuit is electrically connected to n2 third light emitting elements and configured to drive the n2 third light emitting elements to emit light, where both n1 and n2 are integers greater than or equal to 2 and n1 is different from n2.

16. The display substrate of claim 5, wherein the at least one third pixel circuit is electrically connected to n1 third light emitting elements and configured to drive the n1 third light emitting elements to emit light, and the at least one third pixel circuit is electrically connected to n2 third light emitting elements and configured to drive the n2 third light emitting elements to emit light, where both n1 and n2 are integers greater than or equal to 2 and n1 is different from n2.

17. The display substrate of claim 7, further comprising: a plurality of third connection lines located in the first display region, wherein the n1 third light emitting elements or the n2 third light emitting elements are electrically connected by one third connection line.

18. The display substrate of claim 4, wherein the plurality of third conductive lines electrically connected to the plurality of third pixel circuits and the plurality of first conductive lines electrically connected to the plurality of first pixel circuits, which are located in a same group of pixel circuits, are located on opposite sides of the group of pixel circuits in the second direction; or, the plurality of third conductive lines electrically connected to the plurality of third pixel circuits and the plurality of second conductive lines electrically connected to the plurality of second pixel circuits, which are located in a same group of pixel circuits, are located on opposite sides of the group of pixel circuits in the second direction.

19. The display substrate of claim 5, wherein the plurality of third conductive lines electrically connected to the plurality of third pixel circuits and the plurality of first conductive lines electrically connected to the plurality of first pixel circuits, which are located in a same group of pixel circuits, are located on opposite sides of the group of pixel circuits in the second direction; or, the plurality of third conductive lines electrically connected to the plurality of third pixel circuits and the plurality of second conductive lines electrically connected to the plurality of second pixel circuits, which are located in a same group of pixel circuits, are located on opposite sides of the group of pixel circuits in the second direction.

20. The display substrate of claim 6, wherein the plurality of third conductive lines electrically connected to the plurality of third pixel circuits and the plurality of first conductive lines electrically connected to the plurality of first pixel circuits, which are located in a same group of pixel circuits, are located on opposite sides of the group of pixel circuits in the second direction; or, the plurality of third conductive lines electrically connected to the plurality of third pixel circuits and the plurality of second conductive lines electrically connected to the plurality of second pixel circuits, which are located in a same group of pixel circuits, are located on opposite sides of the group of pixel circuits in the second direction.
